(19) United States
(12) Patent Application Publication
(10) Pub. No.: US 2022/0029060 A1
(43) Pub. Date: Jan. 27, 2022

(54) ARRANGEMENT STRUCTURE FOR ELECTRODE OF MICRO LED

(71) Applicant: RYUJIN LAB, INC., Seongnam-si, Gyeonggi-do (KR)

(72) Inventors: Seong Jin PARK, Seogwipo-si (KR); Hong Joo LEE, Seoul (KR); Kihyung KIM, Jeungpyeong-gun (KR)

(73) Assignee: RYUJIN LAB, INC., Seongnam-si, Gyeonggi-do (KR)

(21) Appl. No.: 17/296,649

(22) PCT Filed: Nov. 26, 2019
(86) PCT No.: PCT/KR2019/016381

§ 371 Date: May 25, 2021

(51) Int. Cl. H01L 33/38; H01L 27/15

(52) U.S. Cl. CPC H01L 33/387; H01L 27/156

(57) ABSTRACT

Proposed is an arrangement structure for the electrodes of a micro LED that may perform driving without any problems even when an anode and a cathode constituting parts of the electrodes of a micro LED are rotated and thus the left, right, upper and/or lower sides thereof are changed. The arrangement structure includes: a substrate having an anode and a cathode; an LED anode element fixedly attached to the substrate, and configured to form an anode among electrodes of an LED device; an LED cathode element fixedly attached to the substrate, and configured to form a cathode among the electrodes of the LED device; an anode application element configured to apply a current while connecting the LED anode element to the anode of the substrate; and a cathode application element configured to apply a current while connecting the LED cathode element to the cathode of the substrate.

### TECHNICAL FIELD

The embodiments disclosed herein relate to the design of the directions of electrode elements for the driving of a micro light-emitting diode (LED), the design of a driving substrate, and an arrangement structure for the electrodes of a micro LED formed by fixedly attaching the electrode elements. BACKGROUND ART

In general, a micro LED display refers to a display using micro LEDs having a sire that is about 1/10 of the size of existing LEDs.

Such a micro LED display implies using a substrate, in which significantly small LEDs are embedded, as a display. As a commonly used definition, a micro LED display refers to a display having an element size of 100 μm or less in each of length and width.

However, in order for a micro LED display to be used in small devices such as smartphone displays, it must range from 5 to 10 μm. 100 μm is 0.1 mm, which is only 254 PPI in terms of PPI, so that it is much inferior to an OLED method.

Existing LED displays simply use LEDs as backlights, whereas micro LED displays themselves emit light without liquid crystals. Since the micro LED displays have performance superior to that or existing LED liquid crystal displays in almost all areas such as contrast ratio, response speed, viewing angle, brightness, limit resolution, and lifespan, the application range thereof is gradually increasing.

However, at the current technical level, such micro LED displays have a problem in that it takes a lot of time to place LEDs on a PCB or TFT substrate, so that the price thereof is increased and it is difficult to perform the mass production thereof.

Accordingly, there is a need for a technology that can perform attachment more easily and rapidly in the process of fixedly attaching LEDs to a substrate such as a driving TFT or PCB substrate.

The electrode part of a common LED is composed of an anode and a cathode. Accordingly, when it is attached to a TFT or PCB substrate, it cannot be driven if it is attached in a state misaligned to the left, to the right, upward, or downward. Accordingly, there is the inconvenience of aligning and attaching the common LED.

In particular, in the case of a micro LED, since the size of the micro LED is small, it is necessary to check the alignment of a lot of pixels and attach micro LEDs in order to manufacture a display. Accordingly, a problem arises in that more time is consumed.

As a related art, there is an LED lamp using a micro LED electrode assembly disclosed in Korean Patent No. 10-1429095.

This related art has a problem in that it is cumbersome and takes a lot of time to manufacture a micro LED device because it is necessary to erect a micro LED device and align and fixedly attach the micro LED to an electrode in a one-to-one correspondence.

Therefore, there is a need for a technology capable of overcoming the above-described problems.

Meanwhile, the above-described background technology corresponds to technical information that has been possessed by the present inventor in order to contrive the present invention or that has been acquired in the process of contriving the present invention, and can not necessarily be regarded as well-known technology that had been known to the public prior to the filing of the present invention.

### DISCLOSURE

### Technical Problem

An object of the embodiments disclosed herein is to propose an arrangement structure for the electrodes of a micro LED that may perform driving without any problems even when an anode and a cathode constituting parts of the electrodes of a micro LED are rotated and thus the left, right, upper and/or lower sides thereof are changed.

More specifically, an object of the embodiments disclosed herein is to propose an arrangement structure for the electrodes of a micro LED in which the design of the arrangement structure is changed so that lateral and vertical symmetry is established by changing the asymmetric up, down, left and right sides of an anode and a cathode constituting parts of the electrodes of an existing micro LED and TFT or PCB electrodes that drive current are vertically and laterally symmetrically arranged accordingly, thereby performing driving without any problems regardless of the direction thereof.

### Technical Solution

As a technical solution for accomplishing the above objects, according to an embodiment, there is provided an arrangement structure for the electrodes of a micro light-emitting diode (LED), the arrangement structure including: a substrate having an anode and a cathode; an LED anode element fixedly attached to the substrate, and configured to form an anode among electrodes of an LED device; an LED cathode element fixedly attached to the substrate, and configured to form a cathode among the electrodes of the LED device; an anode application element configured to apply a current while connecting the LED anode element to the anode of the substrate; and a cathode application element configured to apply a current while connecting the LED cathode element to the cathode of the substrate.

Furthermore, a partial area of the substrate may be quartered on a per-90-degree basis and form a first quadrant, a second quadrant, a third quadrant, and a fourth quadrant in a clockwise direction.

Furthermore, the pair of LED anode and cathode elements may form a set with the anode and cathode application elements, each set of elements may be arranged in each of the quadrants of the substrate, and subsequent sets of elements may be arranged in the second to fourth quadrants in a cumulatively rotated form on the per-90-degree basis in the clockwise direction based on a set of elements arranged in the first quadrant.

Furthermore, the LED anode element and the LED cathode element may be respectively connected to the anode application element and the cathode application element while being arranged on the substrate, and may be connected to form vertical and lateral symmetry while forming one circular structure.

Furthermore, the LED anode element may be disposed in a dot shape in the center of the substrate, the LED cathode element may be disposed in a donut shape outside the LED anode element while being coaxial with the LED anode element, the anode application element may be arranged in a dot shape corresponding to the LED anode element, and the cathode application element may be arranged in a dot shape in a part of the circumferential section of the LED cathode element.

Moreover, the anode application element may be disposed in a dot shape in the center of the substrate, the cathode application element may be disposed in a donut shape outside the anode application element while being coaxial with the anode application element, the LED anode element may be arranged in a dot shape corresponding to the anode application element, and the LED cathode element may be arranged in a dot shape in a part of the circumferential section of the cathode application element.

### Advantageous Effects

According to any one of the above-described technical solutions, there is proposed the arrangement structure for the electrodes of a micro LED in which the LED anode element and the LED cathode element constituting parts of the electrodes of a micro LED may form lateral and vertical symmetry with the anode application element and the cathode application element, so that the arrangement structure may perform driving without any problems even when the LED anode element and the LED cathode element are rotated and thus and thus the left, right, upper and/or lower sides thereof are changed.

Furthermore, according to any one of the above-described technical solutions, there is proposed the arrangement structure for the electrodes of a micro LED in which the LED anode element and the LED cathode element are connected to the anode application element and the cathode application element, respectively, in a single circular structure, so that symmetry is maintained even when the left, right, upper and/or lower sides thereof are changed, thereby performing driving without any problems.

Moreover, according to any one of the above-described technical solutions, there is proposed the arrangement structure for the electrodes of a micro LED that when the LED anode element and the LED cathode element are fixedly attached to each other, driving may be performed without any problems even when attachment is performed without alignment, so that a manufacturing process may be rapidly and easily performed.

The effects that can be obtained by the embodiments disclosed herein are not limited to the above-described effects, and other effects that have not been described above will be clearly understood by those having ordinary skill in the art, to which the present invention pertains, from the following description.

### DESCRIPTION OF DRAWINGS

FIG. 1 is a diagram showing the configuration of an arrangement structure for the electrodes of a micro LED according to an embodiment;

FIG. 2 is a diagram showing the configuration of an arrangement structure for electrode application elements according to an embodiment;

FIG. 3 is a diagram illustrating the arrangement structure for the electrodes of a micro LED according to an embodiment; and

FIG. 4 is a diagram showing the configuration of a connection form between the LED device shown in FIG. 1 and the electrode application elements.

### MODE FOR INVENTION

Various embodiments will be described in detail below with reference to the accompanying drawings. The following embodiments may be modified to various different forms and then practiced. In order to more clearly illustrate features of the embodiments, detailed descriptions of items which are well known to those having ordinary skill in the art to which the following embodiments pertain will be omitted. Furthermore, in the drawings, portions unrelated to descriptions of the embodiments will be omitted. Throughout the specification, like reference symbols will be assigned to like portions.

Throughout the specification, when one component is described as being “connected” to another component, this includes not only a case where the one component is ‘directly connected’ to the other component but also a case where the one component is ‘connected to the other component with a third component arranged therebetween.’ Furthermore, when one portion is described as “including” one component, this does not mean that the portion does net exclude another component but means that the portion may further include another component, unless explicitly described to the contrary.

The embodiments will he described in detail below with reference to the accompanying drawings.

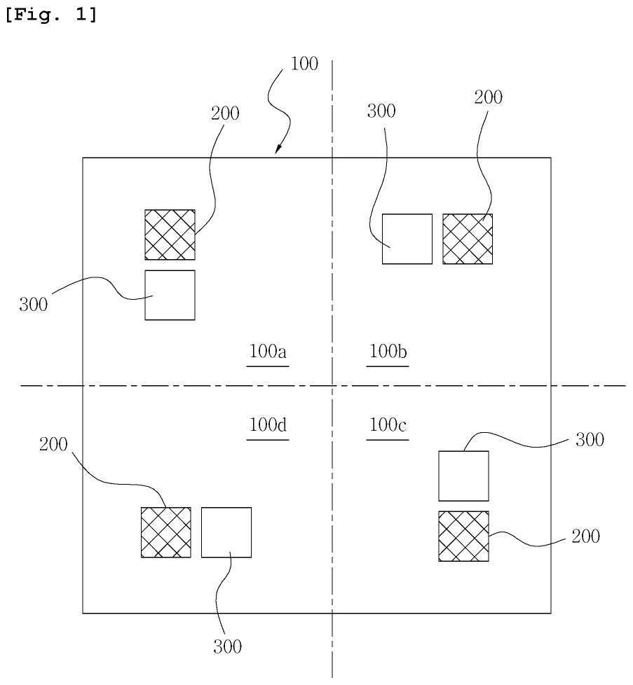

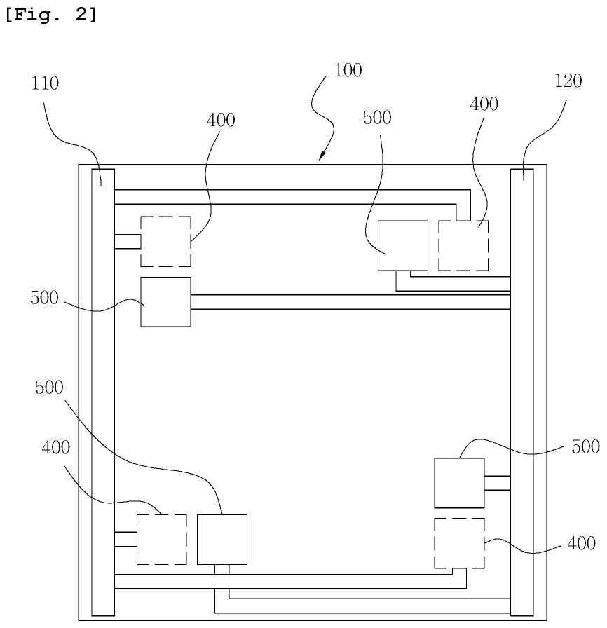

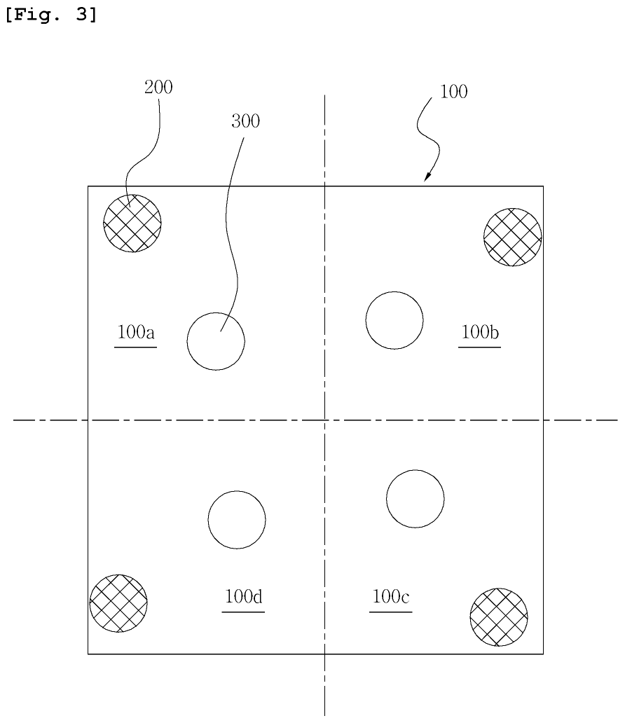

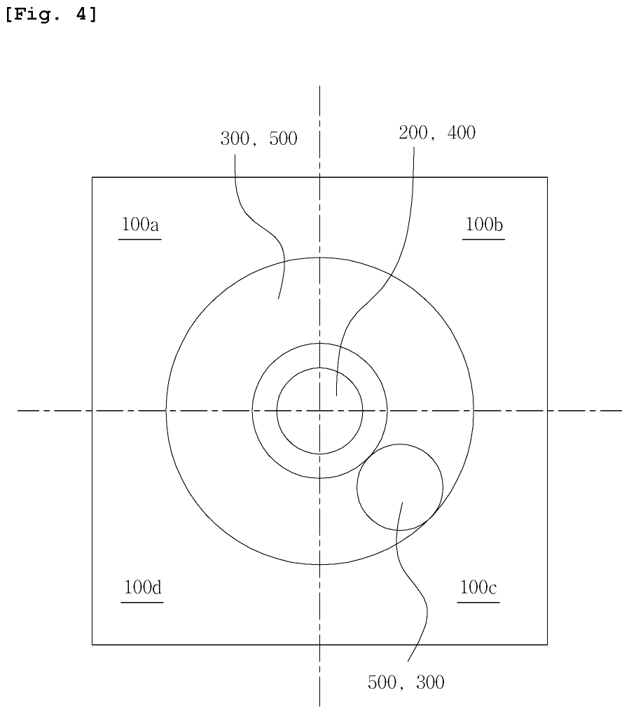

FIG. 1 is a diagram showing the configuration of an arrangement structure for the electrodes of a micro LED according to an embodiment, FIG. 2 is a diagram showing the configuration of an arrangement structure for electrode application elements according to an embodiment, FIG. 3 is a diagram illustrating the arrangement structure for the electrodes of a micro LED according to an embodiment, and FIG. 4 is a diagram showing the configuration of a connection form between the LED device shown in FIG. 1 and the electrode application elements.

According to an embodiment of an arrangement structure for the electrodes of a micro LED, the arrangement structure may include a substrate 100, an LED anode element 200, an LED cathode element 300, an anode application element 400, and a cathode application element 500, as shown in FIGS. 1 and 2.

The substrate 100 serves to provide an attachment surface for the driving of an LED device, and an anode 110 and a cathode 120 may be formed on the substrate 100.

For example, the substrate 100 may include, e.g., a PCB or TFT substrate.

Any one of a glass substrate, a crystal substrate, a sapphire substrate, a plastic substrate, and a flexible polymer film that can be bent may be used as the substrate 100.

More preferably, the substrate 100 may be transparent. However, it is not limited to the above-described types of substrates. In general, any type of base substrate on which electrodes can be formed may be used.

The anode 110 and the cathode 120 are components that form electrodes for supplying power to the LED anode element 200 and the LED cathode element 300 through the anode application element 300 and the cathode application element 400.

In this case, the anode 110 and the cathode 120 may be formed by depositing an electrode formation material on the surface of the substrate 100.

For example, the electrode formation material may be any one or more metal materials selected from the group consisting of aluminum, titanium, indium, gold, and silver, or any one or more transparent materials selected from the group consisting of indium tin oxide (ITO), ZnO:Al, and a CNT-conductive polymer composite. When two or more types of electrode formation materials are used, a first electrode may preferably have a structure in which the two or more types of materials are stacked on top of each other. More preferably, the first electrode may be an electrode in which two types of materials, i.e., titanium and gold, are stacked on top of each other.

Furthermore, in the case of a second electrode, the electrode formation material is any one or more metal materials selected from the group consisting of aluminum, titanium, indium, gold, and silver, or any one or more transparent materials selected from the group consisting of indium tin oxide (ITO), ZnO:Al, and a CNT-conductive polymer composite. When two or more types of electrode formation materials are used, the second electrode may preferably have a structure in which the two or more types of materials are stacked on top of each other.

More preferably, the second electrode may be an electrode in which two types of materials, i.e., titanium and gold, are stacked on top of each other.

In this case, the electrode formation materials used to form the anode 110 and the cathode 120 may be the same or different. The electrode formation materials may be deposited by any one of a thermal evaporation method, an e-beam evaporation method, a sputtering evaporation method, and a screen printing method, and may preferably be deposited by a thermal evaporation method.

In this case, as shown in FIG. 3, a partial area of the substrate 100 may be quartered on a per-90-degree basis and form a first quadrant 100a, a second quadrant 100b, a third quadrant 100c, and a fourth quadrant 100d in a clockwise direction from the top left.

The LED anode element 200 is a component that forms an anode among the electrodes of an LED device while being fixedly attached to the substrate 100.

The LED cathode element 300 is a component that forms a cathode among the electrodes of an LED device while being fixedly attached to the substrate 100.

The LED anode element 200 and the LED cathode element 300 may be used for a micro LED device used in a display.

For example, the LED cathode element 200 and the LED cathode element 300 may be included in a solution in an ink or paste form, and may be arranged while being fixedly attached to the substrate 100.

The anode application element 400 is a component that drives the LED anode element 200 by applying a current while connecting the LED anode element 200 to the anode 110 of the substrate 100.

The cathode application element 500 is a component that drives the LED cathode element 300 by applying a current while connecting the LED cathode element 300 to the cathode 120 of the substrate 100.

The anode application element 400 and the cathode application element 500 may be connected to each other while being fixedly attached to the substrate 100 in a stacked form in which they are stacked on the LED anode element 200 and the LED cathode element 300, respectively.

Meanwhile, as shown in FIGS. 1 and 3, the above-described pair of LED anode and cathode elements 200 and 300 form a set with the anode and cathode application elements 400 and 500, and each set of elements may be arranged in each of the quadrants 100a, 100b, 100c, and 100d of the substrate 100.

In this case, subsequent sets of LED anode and cathode elements 200 and 300 may be sequentially arranged in the second to fourth quadrants 100b to 100d while forming a cumulatively rotated form in the clockwise direction based on the first quadrant 100a.

More specifically, the LED anode element 200 and LED cathode element 300 of the first quadrant 100a may be arranged in the second quadrant 100b after being rotated by 90 degrees, the LED anode element 200 and LED cathode element 300 of the second quadrant 100b may be arranged in the third quadrant 100c after being rotated by 90 degrees again, and the LED anode element 200 and LED cathode element 300 of the third quadrant 100c may be arranged in the fourth quadrant 100d after being rotated by 90 degrees again

It is obvious that the anode application element 400 and the cathode application element 500 may also be arranged at the same positions as the LED anode element 200 and LED cathode element 300 of the first quadrant 100a, as shown in FIG. 2, and may be respectively connected to the anode 110 and cathode 120 of the substrate 100.

Accordingly, the LED anode element 200 and the LED cathode element 300 are arranged while being rotated by 90 degrees in a direction across the substrate 100 in a process in which the LED anode element 200 and the LED cathode element 300 are fixedly attached to the substrate 100, so that they may be arranged more rapidly and easily and driving may be performed without an error in the attachment direction.

Meanwhile, the LED anode element 200 and the LED cathode element 300 are connected to the anode application element 400 and the cathode application element 500, respectively, and are connected in a single circular structure so that lateral and vertical symmetry is established, with the result that driving may be performed without any problems even when lateral or vertical rotation occurs.

More specifically, referring to FIG. 4, the LED anode element 200 may be arranged in a dot shape in the center of the substrate 100, and the LED cathode element 300 may be arranged in a donut shape outside the LED anode element 200 while being coaxial with the LED anode element 200.

In other words, the LED anode element 200 and the LED cathode element 300 may be fixedly attached to form symmetry in vertical and lateral directions while forming a single circle concentric with each other.

In this case, the above-described anode application element 400 may be arranged in a dot shape corresponding to the LED anode element 200, and the cathode application element 500 may be arranged in a dot shape in a portion of the circumferential section of the LED cathode element 300.

In other words, the LED anode element 200 and the LED cathode element 300 may be arranged to be symmetrical vertically and horizontally by forming one circle together with the anode application element 400 and the cathode application element 400.

Meanwhile, the LED cathode element 200 and the LED cathode element 300 may be arranged in a structure opposite to that described above.

More specifically, the anode application element 400 may be arranged in a dot shape in the center of the substrate 100, and the cathode application element 500 may be arranged in a donut shape outside the LED anode element 200 while being coaxial with the anode application element 400.

In other words, the anode application element 400 and the cathode application element 500 may be fixedly attached to form symmetry in vertical and lateral directions while forming a single circle concentric with each other.

In this case, the above-described LED anode element 200 may be arranged in a dot shape corresponding to the anode application element 400, and the LED cathode element 300 may be arranged in a dot shape in a portion of the circumferential section of the cathode application element 500.

A process of manufacturing a micro LED electrode assembly using the arrangement structure for the electrodes of a micro LED including the above-described components will be described.

The LED anode element 200 and the LED cathode element 300 may be arranged while being fixedly attached to the substrate 100 while forming a set of a pair of elements.

In this case, while the substrate 100 is rotated by 90 degrees, a set of LED anode and cathode elements 200 and 300 may be rapidly and easily arranged in each of the quadrants 100a, 100b, 100c, and 100d.

Furthermore, the anode application element 400 and the cathode application element 500 are fixedly attached to positions corresponding to the LED anode element 200 and the LED cathode element 300 through the rotation of the substrate 100, and may then be connected to the anode 110 and the cathode 120 in order not to interfere with each other.

Meanwhile, when the LED anode element 200 and the LED cathode element 300 are arranged in a circular structure, the LED anode element 200 may be arranged, and then the LED cathode element 300 may be fixedly attached in a ring shape along the outside of the LED anode element 200.

In addition, the anode application element 400 may be fixedly attached in a dot shape in a position corresponding to the LED anode element 200, and the cathode application element 500 may be fixedly attached in a dot shape to a part of the circumferential direction of the LED cathode element 300, thereby enabling rapid and easy arrangement.

As described above, the LED anode element 200 and the LED cathode element 300 constituting parts of the electrodes of the micro LED may form vertical and lateral symmetry with the anode application element 400 and the cathode application element 500, so that driving may be performed without any problems even when the LED anode element 200 and the LED cathode element 300 are rotated and thus the left, right, upper and/or lower sides thereof are changed.

The above-described embodiments are intended for illustrative purposes. It will be understood that those of ordinary skill in the art to which the above-described embodiments pertain may easily make modifications into different specific forms without changing the technical spirit or essential features of the above-described embodiments. Therefore, the above-described embodiments are illustrative and are not limitative in all aspects. For example, each component described as being in a single form may be practiced in a distributed form. In the same manner, components described as being in a distributed form may be practiced in an integrated form.

1. An arrangement structure for electrodes of a micro light-emitting diode (LED), the arrangement structure comprising:
a substrate having an anode and a cathode;
an LSD anode element fixedly attached to the substrate, and configured to form an anode among electrodes of an LED device;
an LED cathode element fixedly attached to the substrate, and configured to form a cathode among the electrodes of the LED device;
an anode application element configured to apply a current while connecting the LED anode element to the anode of the substrate; and
a cathode application element, configured to apply a current while connecting the LED cathode element to the cathode of the substrate.

2. The arrangement structure of claim 1, wherein a partial area of the substrate is quartered on a per-90-degree basis and forms a first quadrant, a second quadrant, a third quadrant, and a fourth quadrant in a clockwise direction.

3. The arrangement structure of claim 2, wherein the pair of LED anode and cathode elements form a set with the anode and cathode application elements, each set of elements are arranged in each of the quadrants of the substrate, and subsequent sets of elements are arranged in the second to fourth quadrants in a cumulatively rotated form on the per-90-degree basis in the clockwise direction based on a set of elements arranged in the first quadrant.

4. The arrangement structure of claim 1, wherein the LED anode element and the LED cathode element are respectively connected to the anode application element and the cathode application element while being arranged on the substrate, and are connected to form vertical and lateral symmetry while forming one circular structure.

5. The arrangement structure of claim 4, wherein the LED anode element is disposed in a dot shape in a center of the substrate, the LED cathode element is disposed in a donut shape outside the LED anode element while being coaxial with the LED anode element, the anode application element is arranged in a dot shape corresponding to the LED anode element, and the cathode application element is arranged in a dot shape in a part of a circumferential section of the LED cathode element.

6. The arrangement structure of claim 4, wherein the anode application element is disposed in a dot shape in a center of the substrate, the cathode application element is disposed in a donut shape outside the anode application element while being coaxial with the anode application element, the LED anode element is arranged in a dot shape corresponding to the anode application element, and the LED cathode element is arranged in a dot shape in a part of a circumferential section of the cathode application element.
